(19) United States
(12) Patent Application Publication
(10) Pub. No.: US 2012/0230117 A1
(43) Pub. Date: Sep. 13, 2012

(54) NONVOLATILE SEMICONDCUTOR MEMORY DEVICE

(75) Inventor: Kaoru Hama, Yokohama-shi (JP)

(73) Assignee: KABUSHIKI KAISHA TOSHIBA, Tokyo (JP)

(21) Appl. No.: 13/233,298

(22) Filed: Sep. 15, 2011

(30) Foreign Application Priority Data
Mar. 7, 2011 (JP) 2011-049552

(51) Int. Cl. G11C 16/14

(52) U.S. Cl. 365/185.29

(57) ABSTRACT

According to one embodiment, a nonvolatile semiconductor memory device includes semiconductor regions provided on a substrate and electrically separated from each other, a memory cell block provided in each of the semiconductor regions and includes nonvolatile memory cells, word lines connected to control gates of memory transistors so as to commonly connect memory transistors in a same row, select gate lines connected to gates of select transistors so as to commonly connect select transistors in a same row, and a row decoder configured to apply a first negative voltage to a selected word line from which data is erased, and to apply a second positive voltage to a non-selected word lines from which data is not erased while an erasing voltage is applied to the semiconductor region upon erasing operation.

### CROSS-REFERENCE TO RELATED APPLICATIONS

This application is based upon and claims the benefit of priority from prior Japanese Patent Application No. 2011-049552, filed Mar. 7, 2011, the entire contents of which are incorporated herein by reference.

### FIELD

Embodiments described herein relate generally to a nonvolatile semiconductor memory device.

### BACKGROUND

NAND flash memories and NOR flash memories are widely used as nonvolatile semiconductor memories. Further, a flash memory (hereinafter, called a 2Tr flash memory) that has advantages of both of NAND flash memories and NOR flash memories is proposed. A memory cell of a 2Tr flash memory includes two MOS transistors. On the other hand, one of the MOS transistors functions as a nonvolatile storage unit and includes a laminated structure of a control gate and a floating gate, and a drain thereof is connected to a bit line. The other MOS transistor is used for selection of the memory cell with a source thereof connected to a source line.

An erasing operation of the 2Tr flash memory is performed in units of memory cell blocks formed in the same p-type well region and all memory cells included in a memory cell block are erased at once. Accordingly, memory cells other than those memory cells that should be erased are also erased, increasing the number of times of erasing per memory cell.

### BRIEF DESCRIPTION OF THE DRAWINGS

FIG. 1 is a block diagram of a system LSI according to the present embodiment;

FIG. 2 is a circuit diagram of a partial region of a memory cell array;

FIG. 3 is a sectional diagram of one memory cell block included in the memory cell array;

FIG. 4 is a diagram illustrating voltage relationships in an erasing operation;

FIG. 5 is a flow chart showing a voltage control operation while erasing according to a comparative example;

FIG. 6 is a flow chart showing the voltage control operation while erasing according to the present embodiment;

FIG. 7 is a circuit diagram in which a portion of a row decoder that selects a word line is extracted;

FIG. 8 is a logical value table of the row decoder shown in FIG. 7;

FIG. 9 is a circuit diagram of a power switching circuit included in the row decoder;

FIG. 10 is a circuit diagram of a high-order decoding unit included in the row decoder;

FIG. 11 is a circuit diagram of a row decoder 20 according to a modification;

FIG. 12 is a double-selection logic value table;

FIG. 13 is a quadruple-selection logic value table; and

FIG. 14 is an even-odd-selection logic value table.

### DETAILED DESCRIPTION

In general, according to one embodiment, there is provided a nonvolatile semiconductor memory device comprising:

semiconductor regions provided on a substrate and electrically separated from each other;

a memory cell block provided in each of the semiconductor regions and comprising nonvolatile memory cells arranged in a matrix form, each of the memory cells comprising a memory transistor and a select transistor connected in series, the memory transistor comprising a charge storage layer and a control gate;

word lines connected to control gates of memory transistors so as to commonly connect memory transistors in a same row;

select gate lines connected to gates of select transistors so as to commonly connect select transistors in a same row; and

a row decoder configured to apply a first negative voltage to a selected word line from which data is erased, and to apply a second positive voltage to a non-selected word lines from which data is not erased while an erasing voltage is applied to the semiconductor region upon erasing operation.

The embodiments will be described hereinafter with reference to the accompanying drawings. In the description which follows, the same or functionally equivalent elements are denoted by the same reference numerals, to thereby simplify the description.

### [1. Configuration of System LSI 1]

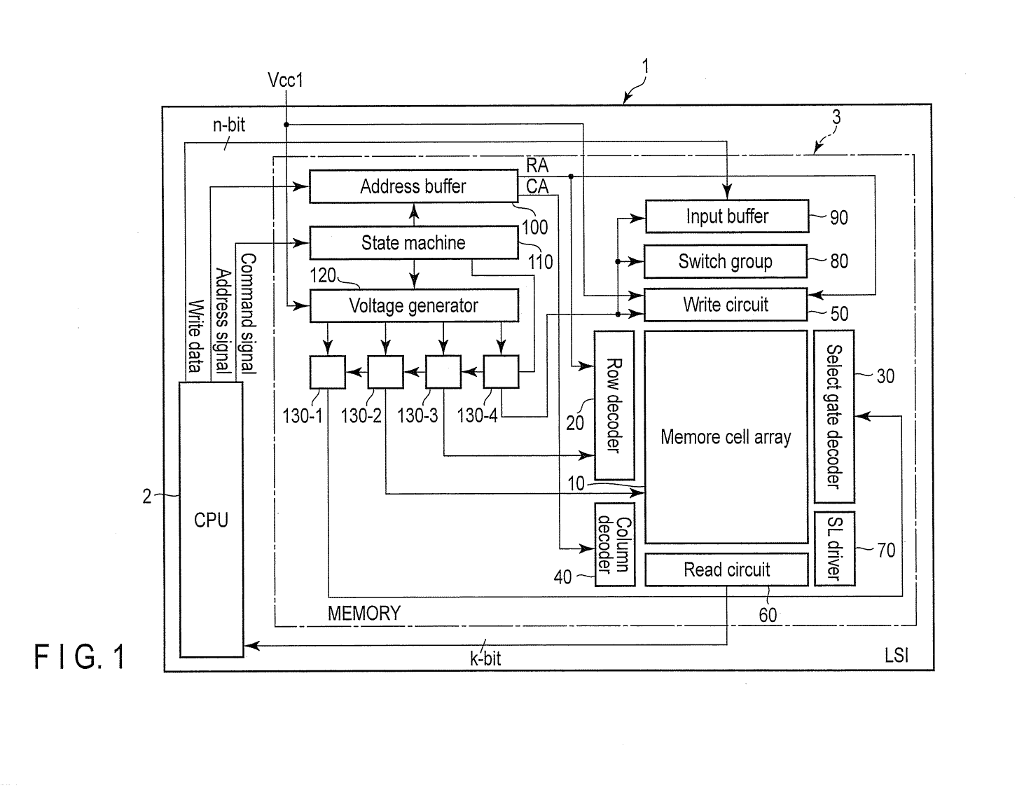

FIG. 1 is a block diagram of the system LSI 1 according to the present embodiment. The system LSI 1 includes a CPU 2 and a 2Tr flash memory (nonvolatile semiconductor memory device) 3. The CPU 2 exchanges data with the flash memory 3. The flash memory 3 includes a memory cell array 10, the row decoder 20, a select gate decoder 30, a column decoder 40, a write circuit 50, a read circuit 60, a source line driver 70, a switch group 80, an input buffer 90, an address buffer 100, a state machine 110, a voltage generator 120, and a voltage switch circuit group 130. A voltage Vcc1 (1.25 to 1.65 V) is supplied to the LSI 1 from outside.

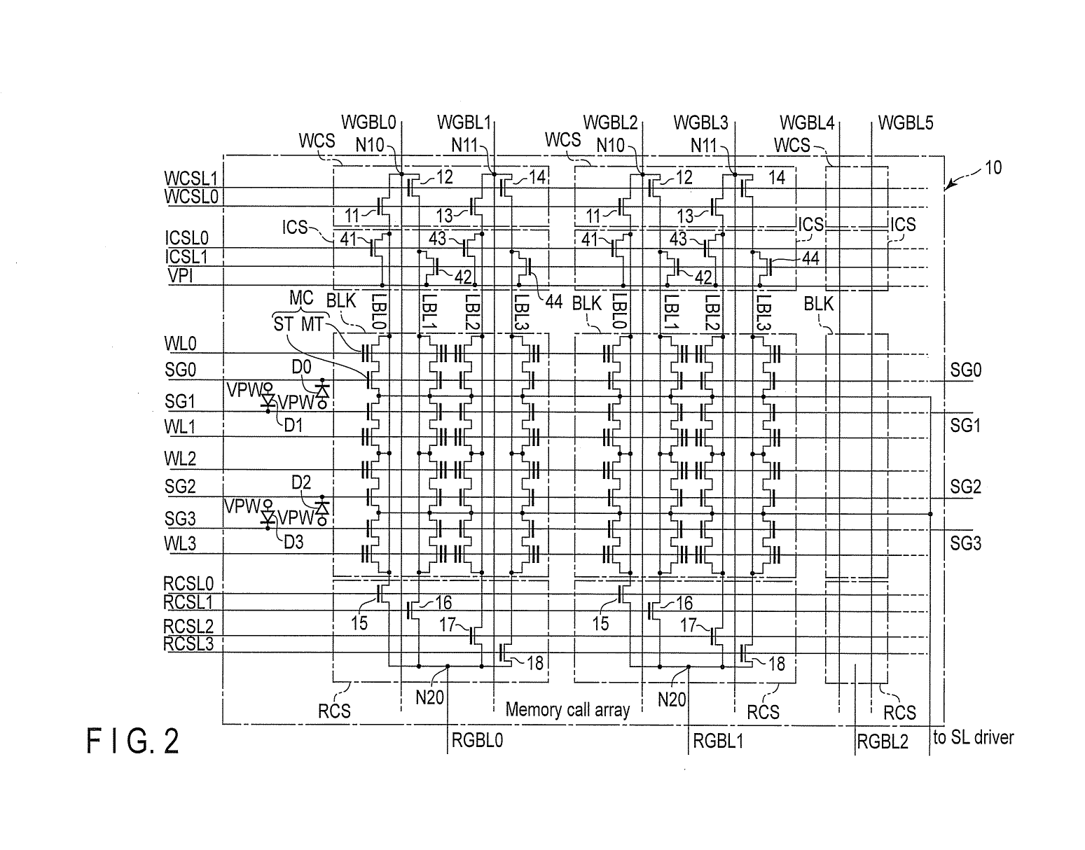

The memory cell array 10 has a plurality of memory cells arranged in a matrix shape. The configuration of the memory cell array 10 will be described using FIG. 2. FIG. 2 is a circuit diagram of a partial region of the memory cell array 10.

The memory cell array 10 has ((m+1)×(n+1), where m and are natural numbers) memory cell blocks BLK, diodes D0 to D(4m−1), and a write column selector WCS, a read column selector RCS, and an inhibition column selector ICS provided for each memory cell block BLK.

Each of the memory cell blocks BLK includes a plurality of memory cells MC arranged in a matrix shape. The memory cell MC is a memory cell of a 2Tr flash memory. That is, each of the memory cells MC has a memory cell transistor MT and a select transistor ST. As the select transistor ST, for example, an n-type MOS transistor is used. The source of the memory cell transistor MT is connected to the drain of the select transistor ST. The memory cell transistor MT includes a laminated gate structure having a floating gate formed on a semiconductor substrate via a gate dielectric film and a control gate formed on the floating gate via an inter-gate dielectric film. The memory cells MC adjacent to each other in the column direction share a drain region of the memory cell transistor MT or a source region of the select transistor ST.

Each of the memory cell blocks BLK includes, for example, (4×4) memory cells MC. The number of the memory cells MC arranged in the column direction is four in FIG. 2, but this number is only an example and may be, for example, eight or 16 and should not be limited. Drain regions of the memory cell transistors MT of the memory cells MC arranged in four columns are each connected to local bit lines LBL0 to LBL3. One end of the local bit lines LBL0 to LBL3 is connected to a write column selector WCS and the other end thereof is connected to a read column selector RCS.

In the memory cell array 10, control gates of the memory cell transistors MT in the same row are commonly connected to one of word lines WL0 to WL(4m−1). Gates of the select transistors ST in the same row are commonly connected to one of select gate lines SG0 to SG(4m−1). While the local bit lines LBL0 to LBL3 described above commonly connect memory cell transistors in each of the memory cell blocks BLK, the word lines WL and the select gate lines SG commonly connect memory sell transistors and select transistors also between memory cell blocks respectively. The word lines WL0 to WL(4m−1) are connected to the row decoder 20. The select gate lines SG0 to SG(4m−1) are connected to the select gate decoder 30. The source of the select transistor ST is commonly connected between a plurality of memory cell blocks BLK and is connected to the source line driver 70.

Next, the configuration of the write column selector WCS will be described. Each of the write column selectors WCS includes four MOS transistors 11 to 14. One end of current paths of the MOS transistors 11 to 14 is connected to one end of the local bit lines LBL0 to LBL3 respectively. Then, the other ends of current paths of the MOS transistors 11 and 12 are commonly connected and the other ends of current paths of the MOS transistors 13 and 14 are commonly connected. A common connection node of the MOS transistors 11 and 12 is called a node N10 and a common connection node of the MOS transistors 13 and 14 is called a node N11. Each gate of the MOS transistors 11 to 14 is connected to one of write column selection lines WCSL0 to WCSL(2m−1). The MOS transistors 11 and 13 included in the write column selectors WCS in the same row are connected to the same write column selection line WCSL(i−1) (i: 1, 3, 5, . . . ) and the MOS transistors 12 and 14 included in the write column selectors WCS in the same row are connected to the same write column selection line WCSLi. The write column selection lines WCSL0 to WCSL(2m−1) are selected by the column decoder 40 while writing.

The nodes N10 and N11 in the write column selector WCS are each connected to one of writing global bit lines WGBL0 to WGBL(2n−1). The writing global bit lines WGBL0 to WGBL(2n−1) commonly connect the nodes N10 or the nodes N11 of the write column selectors WCS in the same column. Then, the writing global bit lines WGBL0 to WGBL(2n−1) are connected to the write circuit 50.

Next, the configuration of the read column selector RCS will be described. Each of the read column selectors RCS includes four MOS transistors 15 to 18. One end of current paths of the MOS transistors 15 to 18 is connected to the other end of the local bit lines LBL0 to LBL3 respectively. Then, the other ends of current paths of the MOS transistors 15 to 18 are mutually commonly connected. A common connection node of the MOS transistors 15 to 18 is called a node N20. Each gate of the MOS transistors 15 to 18 is connected to one of read column selection lines RCSL0 to RCSL(4m−1). Each of the MOS transistors 15 to 18 included in the read column selectors RCS in the same row is connected to the same read column selection lines RCSL0 to RCSL(4m−1). The read column selection lines RCSL0 to RCSL(4m−1) are selected by the column decoder 40 while reading.

The node N20 in the read column selector RCS is connected to one of the reading global bit lines RGBL0 to RGBL(n−1). Each of the reading global bit lines RGBL0 to RGBL(n−1) commonly connects the nodes N20 in the read column selectors RCS in the same column. Then, the reading global bit lines RGBL0 to RGBL(n−1) are connected to the read circuit 60. The number of memory cells in a memory cell block and the numbers of the reading global bit lines RGBL and the writing global bit lines WGBL are not limited to those in the present embodiment.

Next, the configuration of the write inhibit column selector ICS will be described. Each of the write inhibit column selectors ICS includes four MOS transistors 41 to 44. One end of current paths of the MOS transistors 41 to 44 is connected to one end of the local bit lines LBL0 to LBL3 respectively. Then, a write inhibit voltage VPI is commonly applied to the other ends of current paths of the MOS transistors 41 to 44. The write inhibit voltage VPI is generated by the voltage generator 120. Each gate of the MOS transistors 41 to 44 is connected to one of write inhibit column selection lines ICSL0 to ICSL(2m−1). The MOS transistors 41 and 43 included in the write inhibit column selectors ICS in the same row are connected to the same write inhibit column selection line ICSL(i−1) (i: 1, 3, 5, . . . ) and the MOS transistors 42 and 44 included in the write inhibit column selectors ICS in the same row are connected to the same write inhibit column selection line ICSLi. The write inhibit column selection lines ICSL0 to ICSL(2m−1) are selected by the column decoder 40 while writing.

The diodes D0 to D(4m−1) are provided for each of the select gate lines SG0 to SG(4m−1). Then, the cathode of the diodes D0 to D(4m−1) is connected to the select gate lines SG0 to SG(4m−1) and the anode thereof is connected to a semiconductor substrate (p-type well region) where a memory cell array is formed. The diodes D0 to D(4m−1) can prevent an excessive voltage stress from being applied to a gate dielectric film of the select transistor ST in voltage relationships while erasing.

Returning to FIG. 1, the write circuit 50 latches write data and also resets the writing global bit lines WGBL.

The input buffer 90 holds write data provided from the CPU 2.

The switch group 80 transfers write data held by the input buffer 90 to the write circuit 50.

The column decoder 40 decodes a column address signal to obtain a column address decoded signal.

Based on the column address decoded signal, a selection operation of the column selection lines WCSL, RCSL, ICSL is performed.

The read circuit 60 precharges the reading global bit lines RGBL0 to RGBL(n−1) while reading. Then, the read circuit 60 amplifies the read data to the reading global bit lines RGBL0 to RGBL(n−1).

The source line driver 70 controls a voltage of the source line SL.

The address buffer 100 holds an address signal provided from the CPU 2. Then, the address buffer 100 sends a column address signal CA to the column decoder 40 and a row address signal RA to the row decoder 20 and the select gate decoder 30.

The state machine (control circuit) 110 controls the operation of each circuit included in the flash memory 3, performs timing control of writing, erasing, or reading data, and executes a predetermined algorithm determined for each operation based on a command signal provided from the CPU 2.

The voltage generator 120 generates a plurality of internal voltages based on the voltage Vcc1 input from outside. The voltage generator 120 includes a negative charge pump circuit and a positive charge pump circuit. Then, the voltage generator 120 generates negative voltages VBB1(=−6 V) and VBB2(=−8 V) and positive voltages VPP(=12 V) and Vcc2(=3 V).

The voltage switch circuit group 130 receives various voltages generated by the voltage generator 120. The voltage switch circuit group 130 includes voltage switch circuits 130-1 to 130-4. ON/OFF of the voltage switch circuits 130-1 to 130-4 are controlled by the state machine 110. The voltage switch circuit 130-1 applies a voltage to the select gate decoder 30. The voltage switch circuit 130-2 applies a voltage to a p-type well region where memory cell array is formed. The voltage switch circuit 130-3 applies a voltage to the row decoder 20. The voltage switch circuit 130-4 applies voltages to the write circuit 50, the switch group 80 and the input buffer 90.

The row decoder 20 applies voltages to the word lines in writing, erasing and reading data. The select gate decoder 30 applies voltages to the select gate lines in writing, erasing and reading data. Operations of the row decoder 20 and the select gate decoder 30 will be described later.

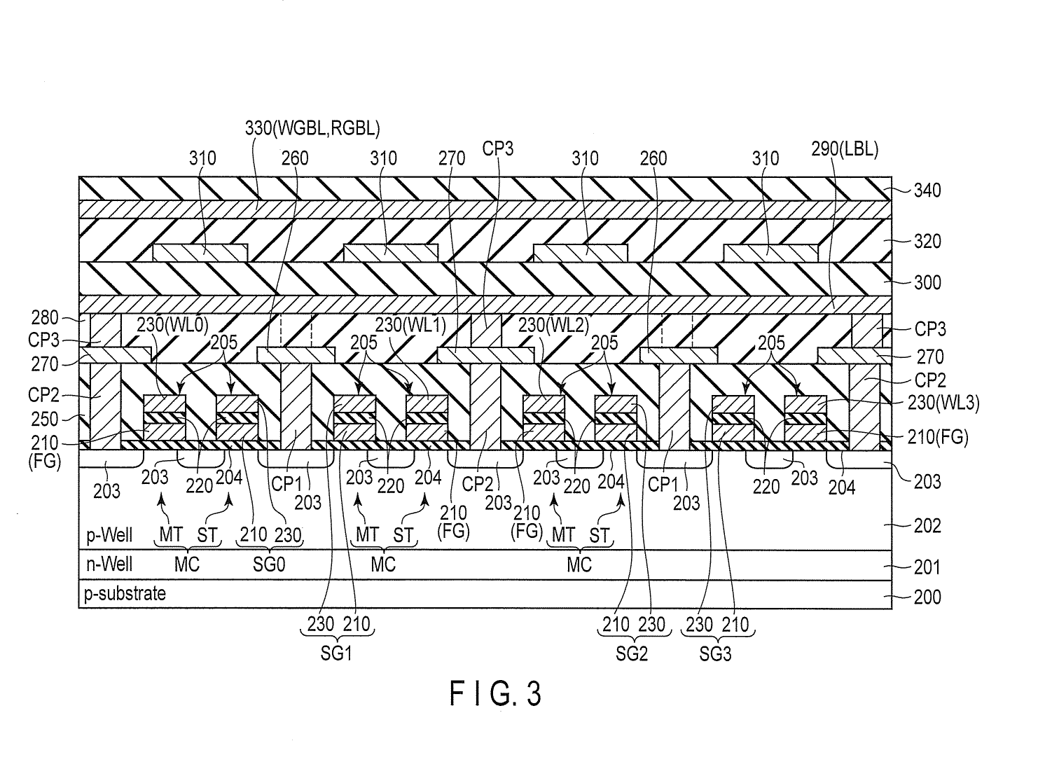

Next, a section structure of the memory cell array 10 will be described using FIG. 3. FIG. 3 is a sectional diagram of one memory cell block BLK included in the memory cell array 10. FIG. 3 is a sectional diagram along the direction of bit lines.

An n-type well region 201 is formed in a surface region of a p-type semiconductor substrate 200 and a p-type well region 202 is formed in the surface region of the n-type well region 201. The p-type well region 202 is formed for each of the memory cell blocks BLK. That is, one memory cell block BLK is formed in one p-type well region 202 and the adjacent memory cell blocks BLK are electrically separated by the n-type well region 201. In other words, a plurality of the p-type well regions 202 provided for each memory cell block BLK is electrically separated by the n-type well region 201.

A gate dielectric film 204 is formed in a device region of the p-type well region 202 and a gate electrode 205 of the memory cell transistor MT and the select transistor ST is formed on the gate dielectric film 204. The gate electrode 205 of the memory cell transistor MT and the select transistor ST has a polysilicon layer 210 formed on the gate dielectric film 204, an inter-gate dielectric film 220 formed on the polysilicon layer 210, and a polysilicon layer 230 formed on the inter-gate dielectric film 220. The inter-gate dielectric film 220 is formed of, for example, a silicon oxide film or an ON film, NO film, or ONO film, which is a laminated structure of a silicon oxide film and a silicon nitride film.

In the memory cell transistor MT, the polysilicon layers 210 are mutually separated between adjacent device regions and function as floating gates (FG). On the other hand, the polysilicon layers 230 are commonly connected between adjacent device regions and function as control gates (word lines WL).

In the select transistor ST, the polysilicon layers 210 are commonly connected between adjacent device regions. Further, the polysilicon layers 230 are commonly connected between adjacent device regions. Then, the polysilicon layers 210 and 230 function as the select gate lines SG. However, only the polysilicon layers 210 function substantially as the select gate lines.

An impurity diffusion layer 203 is formed in the surface of the p-type well region 202 positioned between the adjacent gate electrodes 205. The impurity diffusion layer 203 is shared by adjacent transistors. As described above, the memory cell MC including the memory cell transistor MT and the select transistor ST is formed with relationships therebetween as described below. That is, the adjacent memory cells MC have the select transistors ST or the memory cell transistors MT adjacent to each other. The adjacent transistors share the impurity diffusion layer 203. Therefore, if the select transistors ST are adjacent to each other, the two adjacent memory cells MC are arranged symmetrically with respect to the center of the impurity diffusion layer (source region) 203 shared by the two select transistors ST. Conversely, if the memory cell transistors MT are adjacent to each other, the two memory cells MC are arranged symmetrically with respect to the center of the impurity diffusion layer (drain region) 203 shared by the two memory cell transistors MT.

An interlayer dielectric 250 is formed on the p-type well region 202 as if to cover the memory cell transistor MT and the select transistor ST. A contact plug CP1 reaching the impurity diffusion layer (source region) 203 shared by the two select transistors ST is formed inside the interlayer dielectric 250. A metal wiring film 260 connected to the contact plug CP1 is formed on the interlayer dielectric 250. The metal wiring film 260 functions as the source line SL. Further, a contact plug CP2 reaching the impurity diffusion layer (drain region) 203 shared by the two memory cell transistors MT is formed inside the interlayer dielectric 250. A metal wiring film 270 connected to the contact plug CP2 is further formed on the interlayer dielectric 250.

An interlayer dielectric 280 is formed on the interlayer dielectric 250 as if to cover the metal wiring films 260, 270. A contact plug CP3 reaching the metal wiring film 270 is formed inside the interlayer dielectric 280. A metal wiring film 290 commonly connected to a plurality of the contact plugs CP3 is formed on the interlayer dielectric 280. The metal wiring film 290 functions as one of the local bit lines LBL0 to LBL3. A contact plug reaching the metal wiring film 260 is formed in the interlayer dielectric 280 and a plurality of the source lines 260 is commonly connected by the contact plug in another region (not shown).

An interlayer dielectric 300 is formed on the interlayer dielectric 280 as if to cover the metal wiring film 290. Then, a metal wiring film 310 is formed on the interlayer dielectric 300. The metal wiring film 310 is connected to the polysilicon layer 210 of the select transistor ST in a shunt region (not shown) and functions as a shunt wire of a select gate line. Wires in the metal wiring film 310 are spaced evenly. In the shunt region, at least a portion of the polysilicon layer 230 of the select transistor ST is removed and the shunt wire 310 and the polysilicon layer 210 are connected by a contact plug (not shown) formed in the removed region. The shunt wire 310 is electrically separated from the polysilicon layer 230.

An interlayer dielectric 320 is formed on the interlayer dielectric 300 as if to cover the metal wiring film 310. A metal wiring film 330 functioning as a writing global bit line and a reading global bit line is formed on the interlayer dielectric 320 and further, an interlayer dielectric 340 is formed thereon.

### [2. Operation]

<Write Operation>

Next, the write operation will be described. Data is written to all memory cell blocks in the same row at once. However, there are only two memory cells in each memory cell block to which data is written simultaneously: a memory cell connected to one of the local bit lines LBL0, LBL1, and a memory cell connected to one of the local bit lines LBL2, LBL3. It is assumed that data is written to the memory cell transistors MT connected to the word line WL0 and the local bit lines LBL0, LBL2 and “0” data of the data is written to the memory cell transistor MT connected to the local bit line LBL0 and “1” data is written to the memory cell transistor MT connected to the local bit line LBL2. In other words, memory cells connected to the local bit line LBL0 are selected and memory cells connected to the local bit line LBL2 are made non-selected.

First, the write circuit 50 applies the negative potential VBB1 (−6 V) and a ground voltage VSS (0 V) to the writing global bit lines WGBL0, WGBL1 respectively. Then, the row decoder 20 selects the word line WL0 to apply the positive voltage VPP (12 V) to the selected word line WL0. The select gate decoder 30o applies the negative potential VBB1 (−6 V) to all the select gate lines SG0 to SG(4m−1). The voltage switch circuit 130-2 sets the voltage VPW of the p-type well region 202 where memory cells as a write target are formed to the negative potential VBB1.

The column decoder 40 selects the write column selection line WCSL0 of two write column selection lines connected to the write column selector WCS corresponding to the memory cell block BLK including the selected work line WL0. Accordingly, the MOS transistors 11, 13 in the write column selector WCS are turned on. As a result, the writing global bit line WGBL0 and the local bit line LBL0 are electrically connected and the writing global bit line WGBL1 and the local bit line LBL2 are electrically connected.

The column decoder 40 makes all write column selection lines connected to the write column selector WCS corresponding to the memory cell block BLK that does not include the selected work line WL0 non-selected. Thus, the MOS transistors 11 to 14 in the write column selector WCS corresponding to the memory cell block BLK that does not include the selected work line are turned off.

Further, the column decoder 40 makes all the read column selection lines RCSL0 to RCSL(4m−1) non-selected. Accordingly, the MOS transistors 15 to 18 in all the read column selectors RCS are turned off. Therefore, the reading global bit line RGBL and the local bit lines LBL0 to LBL3 are electrically separated.

Further, the column decoder 40 sets a write inhibit column selection line ICSL1 to a high level (Vcc2) to turn on the MOS transistors 42, 44 connected to the non-selected local bit lines LBL1, LBL3. The write inhibit column selection line ICSL0 connected to the MOS transistors 41, 43 corresponding to the selected local bit lines LBL0, LBL2 is set to a low level (0 V) to turn off the MOS transistors 41, 43. As a result, the write inhibit voltage VPI (0 V) is applied to the non-selected local bit lines LBL1, LBL3.

With the above voltage control, the write voltage (VBB1) is provided from the writing global bit line WGBL0 to the local bit line LBL0 of the memory cell block BLK including the selected word line WL0 via the MOS transistor 11 in the write column selector WCS. Further, the write inhibit voltage VPI (0 V) is provided from the writing global bit line WGBL1 to the local bit line LBL2 of the memory cell block BLK including the selected word line WL0 via the MOS transistor 13.

As a result, the potential difference between the gate and channel is not sufficient (VPP−VPI=12 V) in the memory cell transistor MT connected to the writing global bit line WGBL1 and the word line WL0 and thus, electrons are not injected into the floating gate and the memory cell MC maintains a negative threshold. That is, “1” data is written. Further, VPI is applied to the channel in the memory cell transistor MT connected to the non-selected local bit lines LBL1, LBL3 and the word line WL0 and thus, electrons are not injected into the floating gate and the memory cell MC holds a negative threshold. On the other hand, the potential difference between the gate and channel is sufficient (VPP−VBB1=18 V) in the memory cell transistor MT connected to the writing global bit line WGBL0 and the word line WL0 and thus, electrons are injected into the floating gate by FN tunneling. As a result, the threshold of the memory cell transistor MT changes to a positive one, that is, “0” data is written.

<Read Operation>

Next, the read operation will be described. It is assumed that data is read from the memory cell transistor MT connected to the local bit line LBL0 and the word line WL0. Data is read from one memory cell MC per memory cell block BLK. However, if a plurality of reading global bit lines is present per memory cell block BLK, as many pieces of data as the number of reading global bit lines are read.

First, the column decoder 40 selects the read column selection line RCSL0 of the four read column selection lines RCSL0 to RCSL3 connected to the read column selector RCS corresponding to the memory cell block BLK including the selected select gate line SG0. Accordingly, the MOS transistor 15 in the read column selector RCS corresponding to the memory cell block BLK including the selected select gate line SG0 is turned on.

The column decoder 40 makes all the write column selection lines WCSL0 to WCSL(2m−1) non-selected. Accordingly, all the four MOS transistors 11 to 14 in all the write column selection lines WCSL0 to WCSL(2m−1) are turned off. Therefore, the writing global bit line WGBL and the local bit lines LBL0 to LBL3 are electrically separated.

When reading, the write decoder 50 applies 0 V to all the writing global bit lines WGBL0, WGBL1. The read circuit 60 precharges the reading global bit line RGBL0 with a predetermined precharge voltage.

The select gate decoder 30 selects (high level: Vcc2) the select gate line SG0. The row decoder 20 makes all the word lines WL0 to WL(4m−1) non-selected (0 V). The voltage switch circuit 130-2 sets the voltage VPW of the p-type well region 202 where memory cells as a read target are formed to 0 V. Further, the source line driver 70 sets the potential of the source line to 0 V.

With the above voltage control, the select transistor ST connected to the select gate line SG0 is turned on and if data written to the memory cell transistor MT connected to the selected word line WL0 and the selected local bit line LBL0 is “1”, a current flows from the reading global bit line RGBL0 to the source line. On the other hand, if the written data is “0”, no current flows. Then, the read circuit 60 amplifies a potential change of the reading global bit line caused by the current flowing through the memory cell MC.

<Erasing Operation>

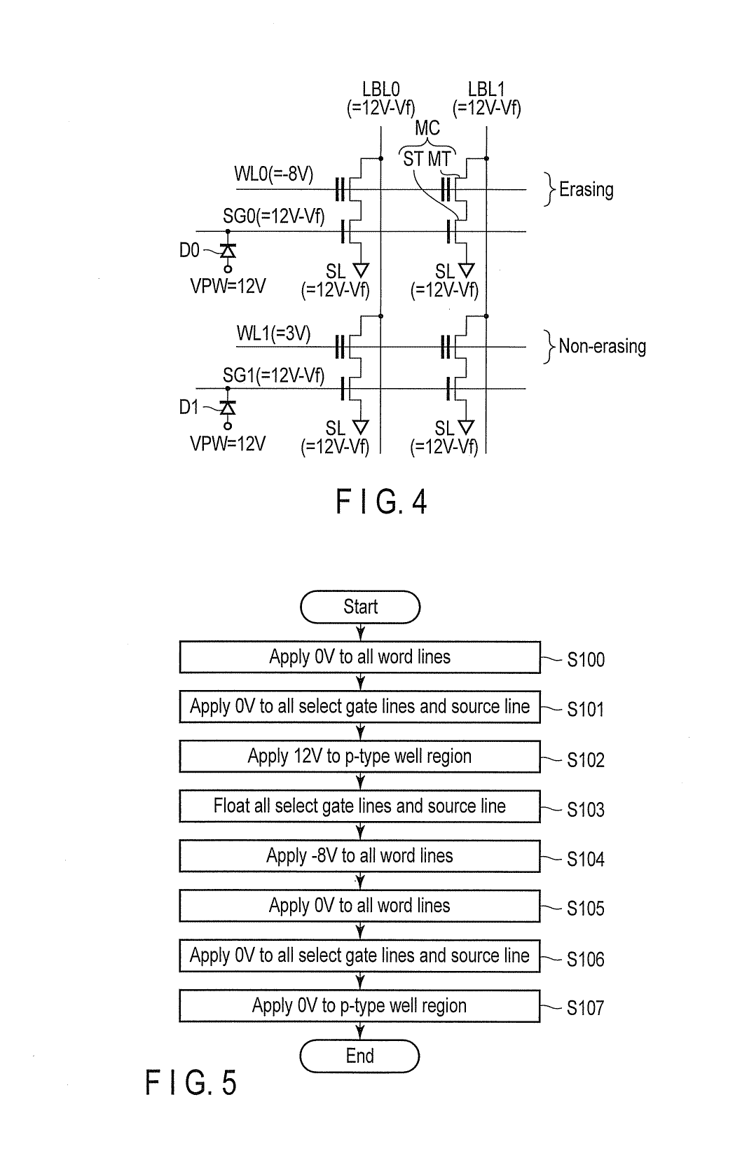

Next, the erasing operation will be described. In the present embodiment, data is erased in units of pages, each page being comprised of the memory cell MC connected to one word line in the selected memory cell block. FIG. 4 is a diagram illustrating voltage relationships in an erasing operation. The erasing operation is performed by pulling out electrons from the floating gate by FN tunneling. It is assumed that data for one page of the memory cell MC connected to the word line WL in the selected memory cell block is erased.

In the erasing operation, all the MOS transistors 11 to 18 are turned off. Therefore, all the writing global bit lines WGBL0, WGBL1, the reading global bit line RGBL0, and all the local bit lines LBL0 to LBL3 are set into a floating state.

The row decoder 20 selects the word line WL0 and applies the negative voltage VBB2 (−8 V) to the selected word line WL0. The row decoder 20 also applies the positive voltage Vcc2 (3 V) to non-selected word lines other than the selected word line WL0. The voltage switch circuit 130-2 sets the voltage VPW of the p-type well region 202 where the selected memory cell block is formed to the erasure voltage (12 V). The select gate decoder 30 sets all the select gate lines SG0 to SG3 into a floating state.

With the positive voltage (12 V) being applied to the p-type well region 202, a forward bias is applied to the diodes D0 to D3. Therefore, if the voltage drop in the diodes D0 to D3 is Vf (for example, 0.7 V), the potential of all the select gate lines SG0 to SG3 rises to (12 V−Vf). The source line SL is set into a floating state by the source line driver 70. If the voltage drop due to a parasitic diode of the select transistor ST is Vf, the potential of the source line SL rises to (12 V−Vf).

With the above voltage control, the electrons are pulled out of the floating gate of the memory cell transistor connected to the selected word line WL0 into the p-type well region 202 by FN tunneling. Accordingly, data of the memory cell MC connected to the selected word line WL0 is erased and the threshold voltage becomes negative. In memory cell transistors connected to the non-selected word lines WL1 to WL3, on the other hand, the potential difference between the control gate and the p-type well region 202 is small and thus, electrons are not pulled out of the floating gate and data is not erased. In this manner, only data of one page in the selected memory cell block is erased.

Next, a voltage control sequence when erasing will be described. When data of all memory cells in the selected memory cell block is erased at once as in the past, a problem of erroneous erasing does not arise. In the present embodiment, however, only a portion of memory cells in the selected memory cell block is erased and thus, there is the possibility that erroneous erasing of data of a memory cell that should not be erased occurs.

First, a voltage control sequence when all memory cells in the selected memory cell block are erased at once (comparative example) will be described. FIG. 5 is a flow chart showing a voltage control operation while erasing according to a comparative example. The voltage control described below is exercised for elements provided in the selected memory cell block.

First, initial settings are made in step S100 and step S101. That is, the low-level voltage (0 V) is applied to all word lines (step S100). Subsequently, the low-level voltage (0 V) is applied to all select gate lines and source lines (step S101).

Subsequently, the positive voltage VPP (12 V) is applied to the p-type well region where the selected memory cell block is formed (step S102). Subsequently (at almost the same time as the step S102), all select gate lines and source lines are set into a floating state (step S103). Accordingly, the potential of all the select gate lines and the source lines rises to (12 V−Vf). The reason for executing the steps S102 and S103 at almost the same time is that a consumption current is prevent from increasing by biasing the diodes D0 to D3 in a forward direction at switching.

Subsequently, the negative voltage VBB2 (−8 V) is applied to all the word lines (step S104). Accordingly, the erasing operation is performed so that data of all memory cells in the selected memory cell block is erased. If the above state is maintained in a sufficient time, a charge is extracted from the floating gate by an FN tunneling.

Subsequently, a voltage recovery operation is performed in steps S105 to S107. That is, the low-level voltage (0 V) is applied to all word lines (step S105). Subsequently, the low-level voltage (0 V) is applied to all select gate lines and source lines (step S106). Subsequently, the low-level voltage (0 V) is applied to the p-type well region where the selected memory cell block is formed (step S107).

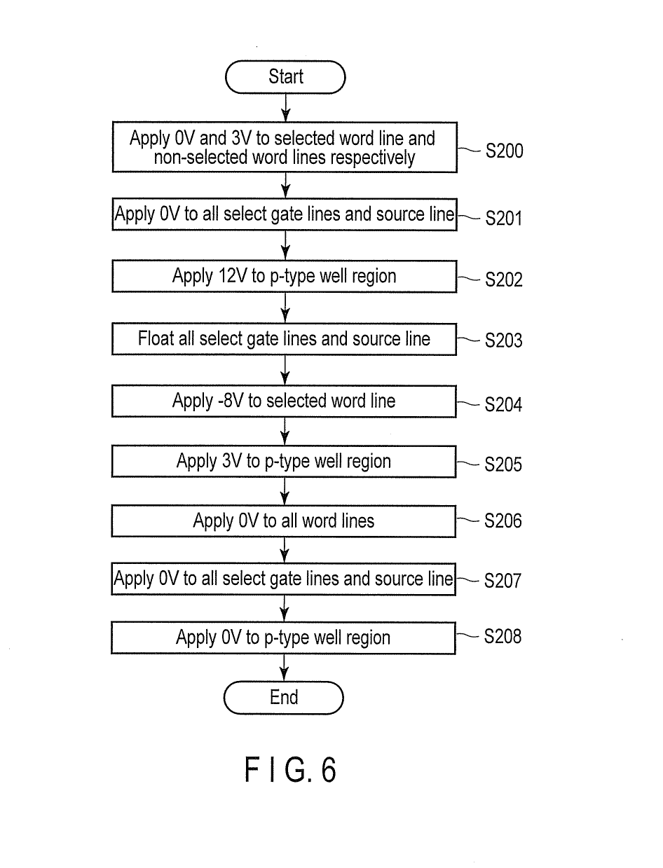

In the voltage recovery operation in FIG. 5, potentials of the word lines, select gate lines, and source lines drop significantly while the potential of the p-type well region is at 12 V. Thus, if the voltage control sequence in FIG. 5 is applied to the erasing operation in the present embodiment, the potential of non-selected word lines drops due to disturbances caused by coupling or the like, which may lead to erroneous erasing of data of a memory cell that should not be erased. A voltage control sequence while erasing to control such erroneous erasing will be described below. FIG. 6 is a flow chart showing the voltage control operation while erasing according to the present embodiment. The voltage control described below is exercised for elements provided in the selected memory cell block.

First, initial settings are made in step S200 and step S201. That is, the row decoder 20 applies the low-level voltage (0 V) and the high-level voltage (3 V) to the selected word line and non-selected word lines respectively (step S200). Subsequently, the select gate decoder 30 applies the low-level voltage (0 V) to all select gate lines and the source line driver 70 applies the low-level voltage (0 V) to the source line SL (step S201).

Subsequently, the voltage switch circuit 130-2 applies the positive voltage VPP (12 V) to the p-type well region 202 where the selected memory cell block is formed (step S202). Subsequently (at almost the same time as the step S202), the select gate decoder 30 sets all select gate lines into a floating state and the source line driver 70 sets the source line SL into a floating state (step S203). Accordingly, the potential of all the select gate lines and the source lines rises to (12 V−Vf).

Subsequently, the row decoder 20 applies the negative voltage VBB2 (−8 V) to the selected word line (step S204). Accordingly, the erasing operation is performed and only data of memory cells connected to the selected word line in the selected memory cell block is erased.

Subsequently, a voltage recovery operation is performed in steps S205 to S208. That is, the voltage switch circuit 130-2 applies the high-level voltage (3 V) to the p-type well region 202 where the selected memory cell block is formed (step S205). Subsequently, the row decoder 20 applies the low-level voltage (0 V) to all word lines (step S206). Subsequently, the select gate decoder 30 applies the low-level voltage (0 V) to all select gate lines and the source line driver 70 applies the low-level voltage (0 V) to the source line SL (step S207). Subsequently (at almost the same time as the step S207), the voltage switch circuit 130-2 applies the low-level voltage (0 V) to the p-type well region 202 where the selected memory cell block is formed (step S208).

In the voltage recovery operation in FIG. 6, two stages are prepared for recovery of the p-type well region 202 to 0 V. In the first stage, the potential of the p-type well region 202 is temporarily set to 3V. Then, all word lines, all select gate lines, and the source line SL are set to 0 V. Then, in the second stage, the potential of the p-type well region 202 is set to 0 V. Accordingly, the p-type well region 202 is set to a sufficiently low voltage when potentials of the word lines, select gate lines and source line significantly drop, which suppresses erroneous erasing due to disturbances. As a result, data of memory cells that should not be erased can be held. For the above voltage control sequence, the 2Tr-type nonvolatile memory can execute a page-erase operation.

### [3. Configuration Example of the Row Decoder 20]

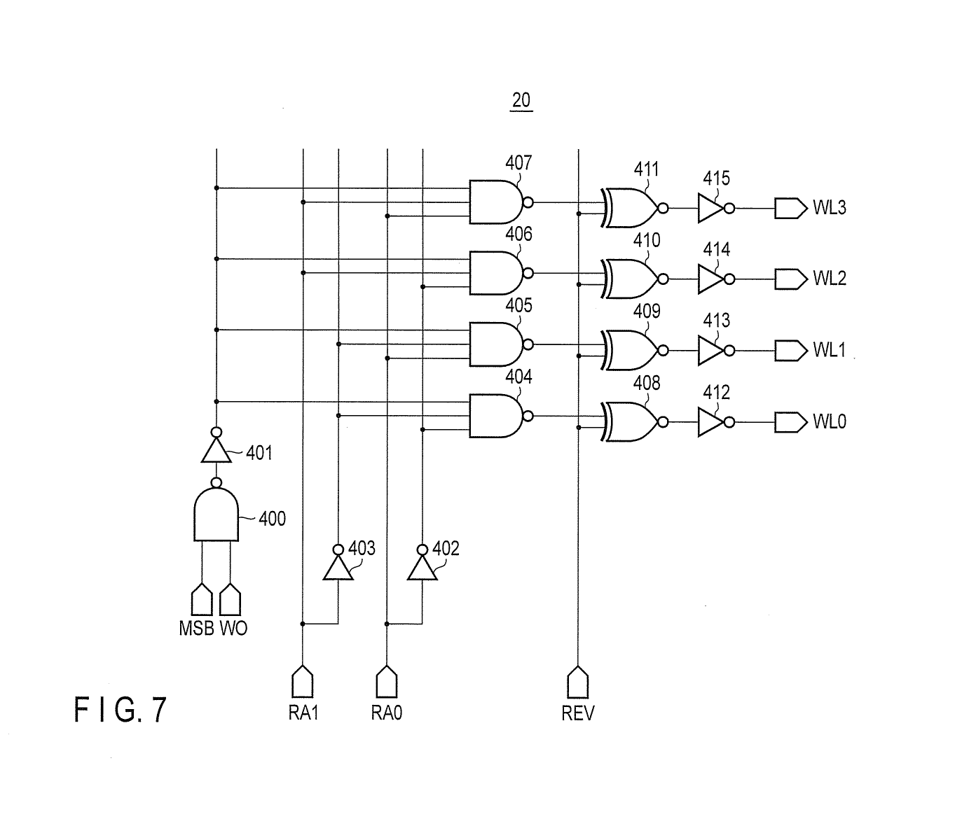

Next, the configuration of the row decoder 20 will be described. FIG. 7 is a circuit diagram in which a portion of the row decoder 20 that selects a word line is extracted.

The row decoder 20 includes NAND circuits 400, 404 to 407, inverter circuits 401 to 403, 412 to 415, and XNOR (exclusive NOR) circuits 408 to 411.

A row high-order signal MSB is input to a first input terminal of the NAND circuit 400 and a word line open signal WO from the state machine 110 is input to a second input terminal thereof. The row high-order signal MSB summarizes and represents signals higher than row address signals RA0, RA1 and includes row address signals and block selection signals higher than the row address signals RA0, RA1. The word line open signal WO is used to open, that is, set to a low level all word lines disposed in the selected memory cell block.

An output terminal of the NAND circuit 400 is connected to each of third input terminals of the NAND circuits 404 to 407 via the inverter circuit 401. The row address signal RA0 sent from the address buffer 100 is input to each of first input terminals of the NAND circuits 405, 407. An inverted signal obtained by the row address signal RA0 being inverted by the inverter circuit 402 is input to each of first input terminals of the NAND circuits 404, 406. The row address signal RA1 sent from the address buffer 100 is input to each of second input terminals of the NAND circuits 406, 407. An inverted signal obtained by the row address signal RA1 being inverted by the inverter circuit 403 is input to each of second input terminals of the NAND circuits 404, 405.

Output terminals of the NAND circuits 404 to 407 are connected to first input terminals of the XNOR circuits 408 to 411. An adverse selection signal REV from the state machine 110 is input to each of second input terminals of the XNOR circuits 408 to 411. If the adverse selection signal REV is at a high level, the logic of word line selection/non-selection is reversed. Output terminals of the XNOR circuits 408 to 411 are connected to the word lines WL0 to WL3 via the inverter circuits 412 to 415 respectively.

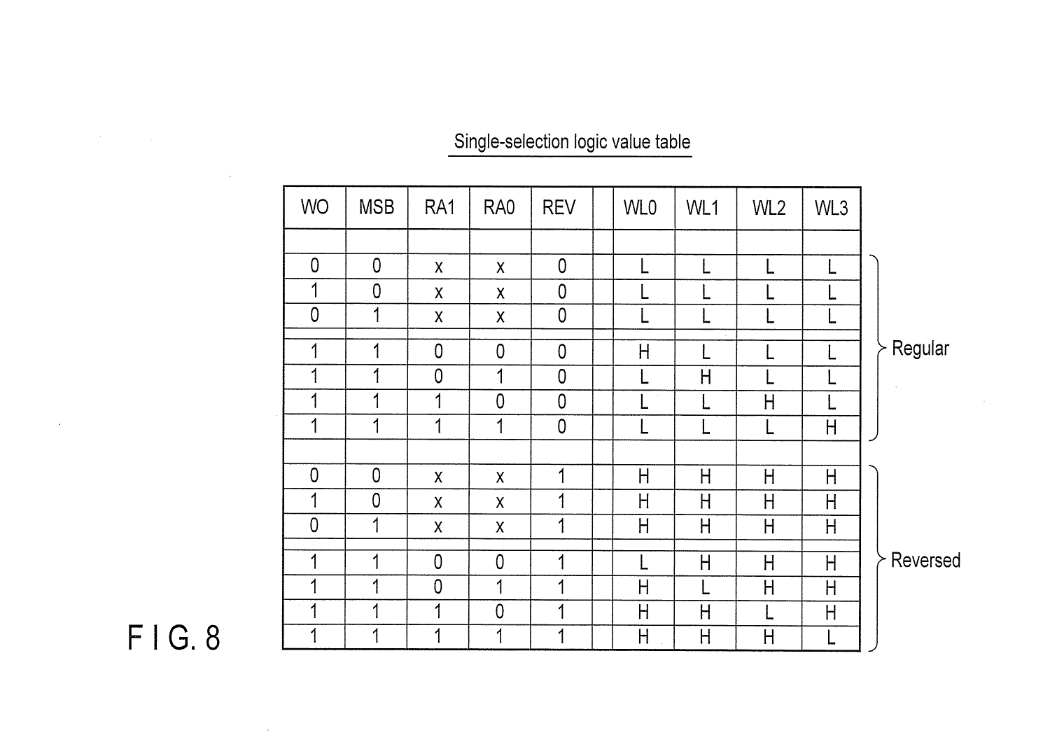

FIG. 8 is a logical value table of the row decoder 20 shown in FIG. 7. “x” in FIG. 8 indicates non-use (Don't care).

As shown in FIG. 8, one of the word lines WL0 to WL3 can be set to a high level in accordance with the row address signals RA0, RA1, that is, a single selection can be made. The single selection is shown in the fields of “Regular” in FIG. 8. All the word lines WL0 to WL3 can be set to the low level by setting the word line open signal WO to the high level. Further, a single reversed selection in which the logic of the word lines WL0 to WL3 is reversed can be made by setting the adverse selection signal REV to a high level. The single reversed selection is shown in the fields of “Reversed” in FIG. 8. Therefore, the row decoder 20 having a function that switches the word line specified by a row address signal to a high level (write) or conversely a low level (erase) can be realized. Incidentally, voltages of the high level and the low level of a word line can arbitrarily be set by changing the level of voltages supplied to the NAND circuits, XNOR circuits, and inverter circuits.

By using the row decoder 20 shown in FIG. 8, voltage control in which the negative voltage VBB2 (−8 V) is applied to only the selected word line and the high-level voltage (3 V) is applied to non-selected word lines while erasing can be exercised. Further, the row decoder 20 can also realize a write operation.

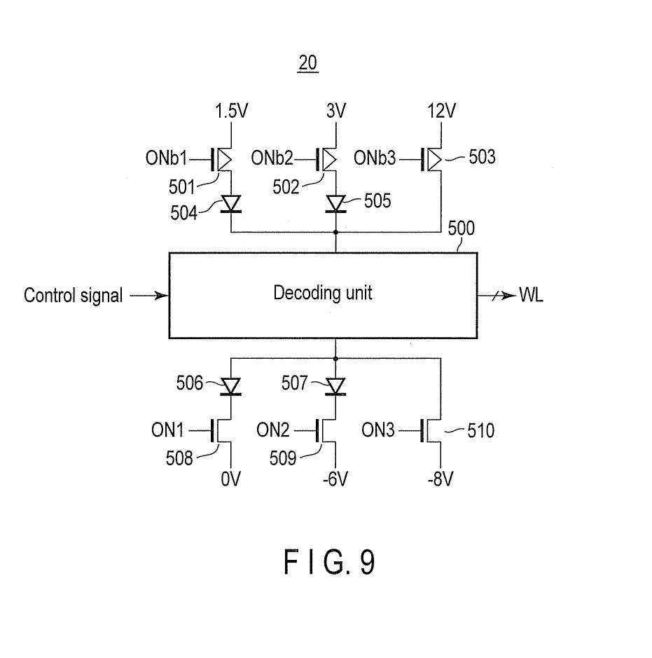

Next, an example of a switching circuit that switches the power supply of the row decoder 20 will be described. FIG. 9 is a circuit diagram of a power switching circuit included in the row decoder 20.

The row decoder 20 includes, in addition to a decoding unit 500, p-type MOS transistors 501 to 503, diodes 504 to 507, and n-type MOS transistors 508 to 510.

1.5 V is supplied to the source of the p-type MOS transistor 501 from the voltage generator 120, a gate voltage ONb1 is supplied to the gate thereof from the state machine 110, and the drain thereof is connected to the anode of the diode 504. The cathode of the diode 504 is connected to the decoding unit 500.

3 V is supplied to the source of the p-type MOS transistor 502 from the voltage generator 120, a gate voltage ONb2 is supplied to the gate thereof from the state machine 110, and the drain thereof is connected to the anode of the diode 505. The cathode of the diode 505 is connected to the decoding unit 500.

12 V is supplied to the source of the p-type MOS transistor 503 from the voltage generator 120, a gate voltage ONb3 is supplied to the gate thereof from the state machine 110, and the drain thereof is connected to the decoding unit 500.

0 V is supplied to the source of the n-type MOS transistor 508 from the voltage generator 120, a gate voltage ON1 is supplied to the gate thereof from the state machine 110, and the drain thereof is connected to the cathode of the diode 506. The anode of the diode 506 is connected to the decoding unit 500.

−6 V is supplied to the source of the n-type MOS transistor 509 from the voltage generator 120, a gate voltage ON2 is supplied to the gate thereof from the state machine 110, and the drain thereof is connected to the cathode of the diode 507. The anode of the diode 507 is connected to the decoding unit 500.

−8 V is supplied to the source of the n-type MOS transistor 510 from the voltage generator 120, a gate voltage ON3 is supplied to the gate thereof from the state machine 110, and the drain thereof is connected to the decoding unit 500.

As shown in FIG. 9, it is desirable to connect the diodes 504, 505 for backflow prevention to the p-type MOS transistors 501, 502 having voltages lower than the voltage of the p-type MOS transistor 503. Similarly, it is desirable to connect the diodes 506, 507 for backflow prevention to the n-type MOS transistors 508, 509 having voltages higher than the voltage of the n-type MOS transistor 510.

The decoding unit 500 corresponds to the circuit in FIG. 7. After voltage conversion by a level shifter (not shown), various control signals input to the row decoder 20 from the state machine 110 are sent to the decoding unit 500. Further, after voltage conversion by a level shifter (not shown), the gate voltage input to the row decoder 20 from the state machine 110 is supplied to a MOS transistor.

The row decoder 20 configured as shown in FIG. 9 can be switched to a plurality of power supplies. Thus, by using the row decoder 20, write operations, erasing operations, and read operations can be performed by using desired power supplies.

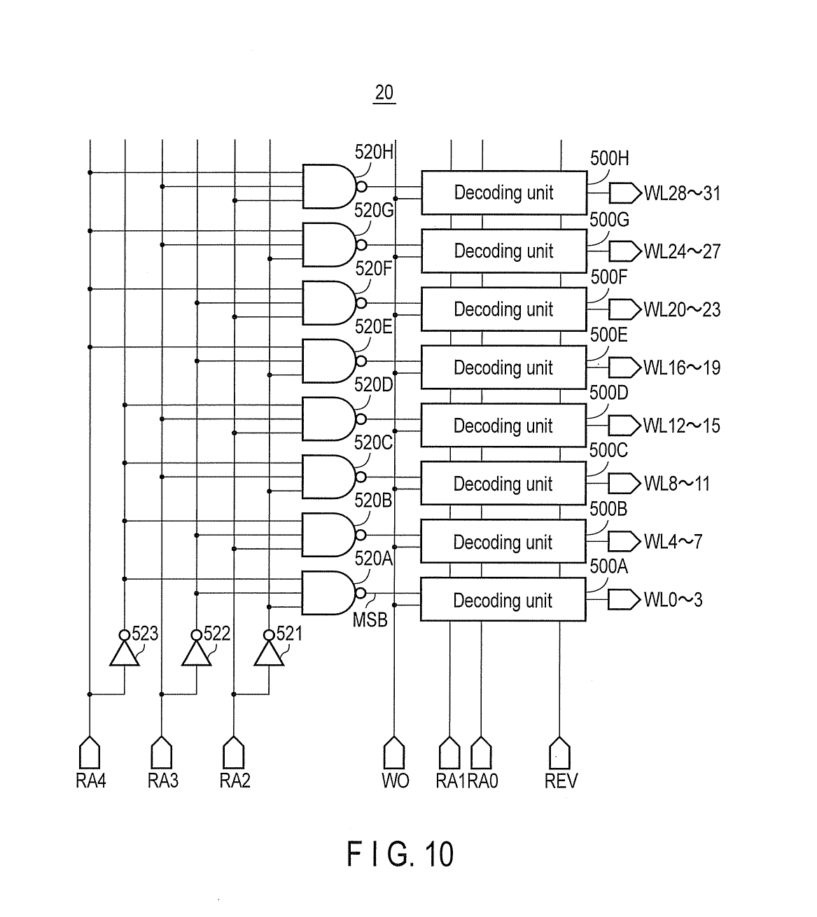

Next, an example of the configuration of a higher-order decoding unit than the decoding unit shown in FIG. 7 will be described. FIG. 10 is a circuit diagram of a high-order decoding unit included in the row decoder 20. For example, the row decoder 20 is assumed to be able to make a selection from 32 word lines WL0 to WL31.

The row decoder 20 includes eight low-order decoding units 500A to 500H, eight NAND circuits 520A to 520H, and three inverter circuits 521 to 523. Each of the low-order decoding units 500A to 500H corresponds to the circuit in FIG. 7. Four word lines are connected to each of the low-order decoding units 500A to 500H.

The NAND circuits 520A to 520H and the inverter circuits 521 to 523 decode row address signals RA2 to RA4 sent from the address buffer 100. The NAND circuits 520A to 520H supply a row high-order signal MSB to the low-order decoding units 500A to 500H respectively.

### [4. Modification]

The number of selected word lines, that is, the number of word lines to be erased may be one, as in the above description, or two or more. The configuration of the row decoder 20 capable of selecting a plurality of word lines while erasing will be described below.

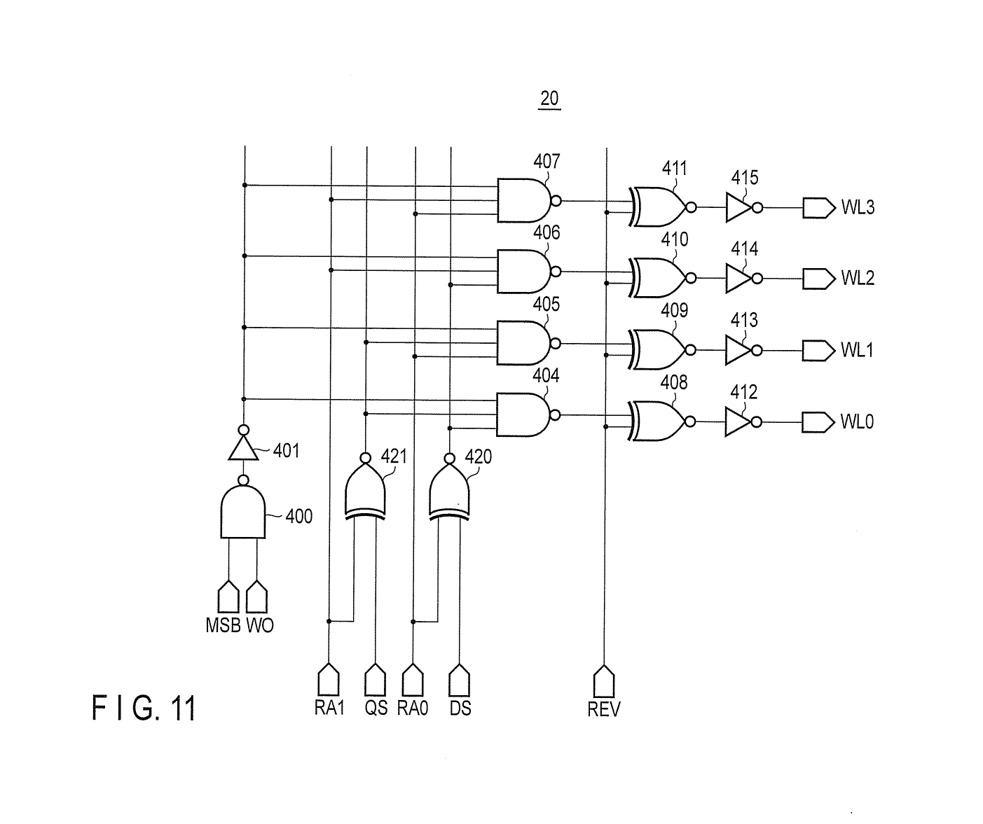

FIG. 11 is a circuit diagram of the row decoder 20 according to a modification. The row decoder 20 includes the NAND circuits 400, 404 to 407, the inverter circuits 401, 412 to 415, the XNOR circuits 408 to 411, and XNOR circuits 420, 421.

The row address signal RA0 is input to a first input terminal of the XNOR circuit 420 from the address buffer 100 and a double-selection signal DS is input to a second input terminal thereof from the state machine 110. The double-selection signal DS is used to enable a selection of two word lines simultaneously. An output terminal of the XNOR circuit 420 is connected to each of the first input terminals of the NAND circuits 404, 406.

The row address signal RA1 is input to a first input terminal of the XNOR circuit 421 from the address buffer 100 and a quadruple-selection signal QS is input to a second input terminal thereof from the state machine 110. The quadruple-selection signal QS is used to enable a selection of four word lines simultaneously. An output terminal of the XNOR circuit 421 is connected to each of the second input terminals of the NAND circuits 404, 405. The other configuration is the same as that in FIG. 7.

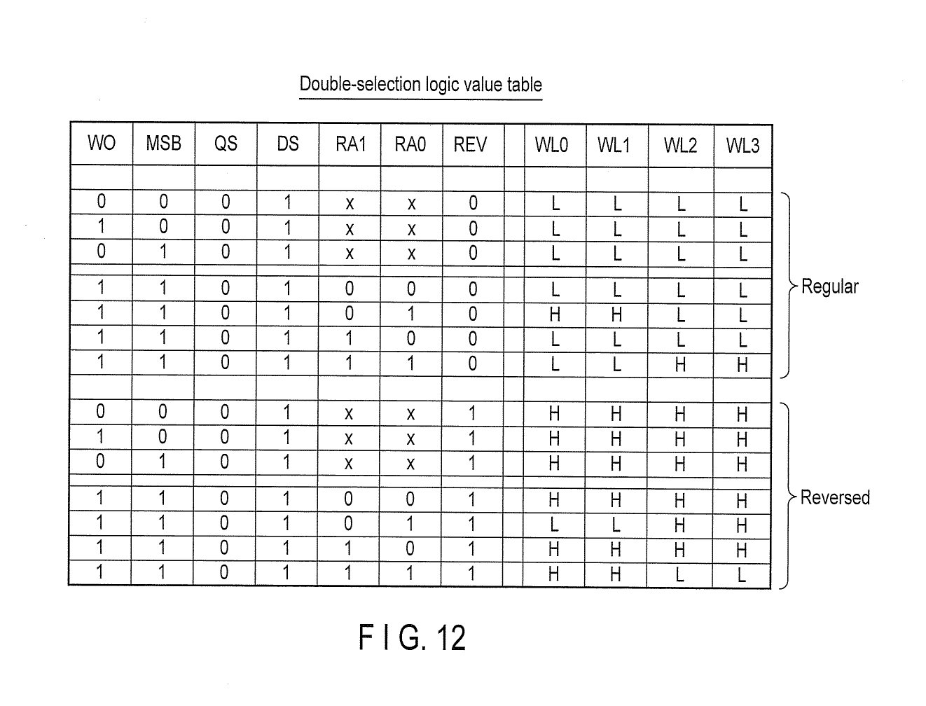

FIG. 12 is a logic value table of double selection that selects two word lines simultaneously. The word lines WL0, WL1 or the word lines WL2, WL3 can be selected simultaneously by setting the double-selection signal DS to a high level. A reversed selection in which the logic of the word lines WL0 to WL3 is reversed can be made by setting the adverse selection signal REV to a high level.

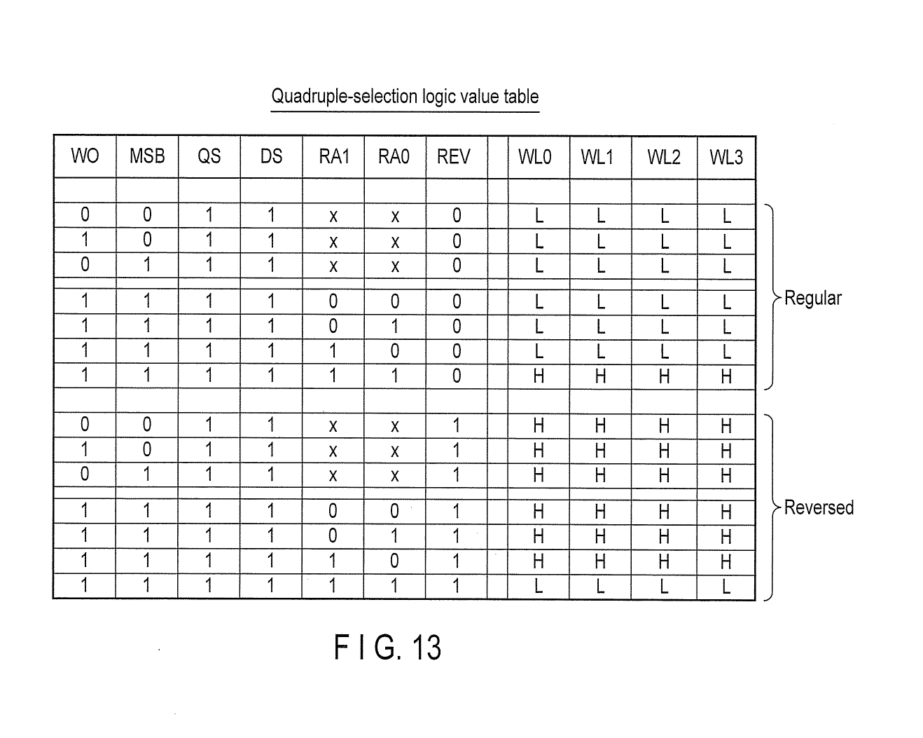

FIG. 13 is a logic value table of quadruple selection that selects four word lines simultaneously. The four word lines WL0 to WL3 can be selected simultaneously by setting both the double-selection signal DS and the quadruple-selection signal QS to a high level. A reversed selection in which the logic of the word lines WL0 to WL3 is reversed can be made by setting the adverse selection signal REV to a high level. The example in FIG. 13 is used when four word lines selected by the high-order row decoder and belonging to the low-order row decoder are selected simultaneously.

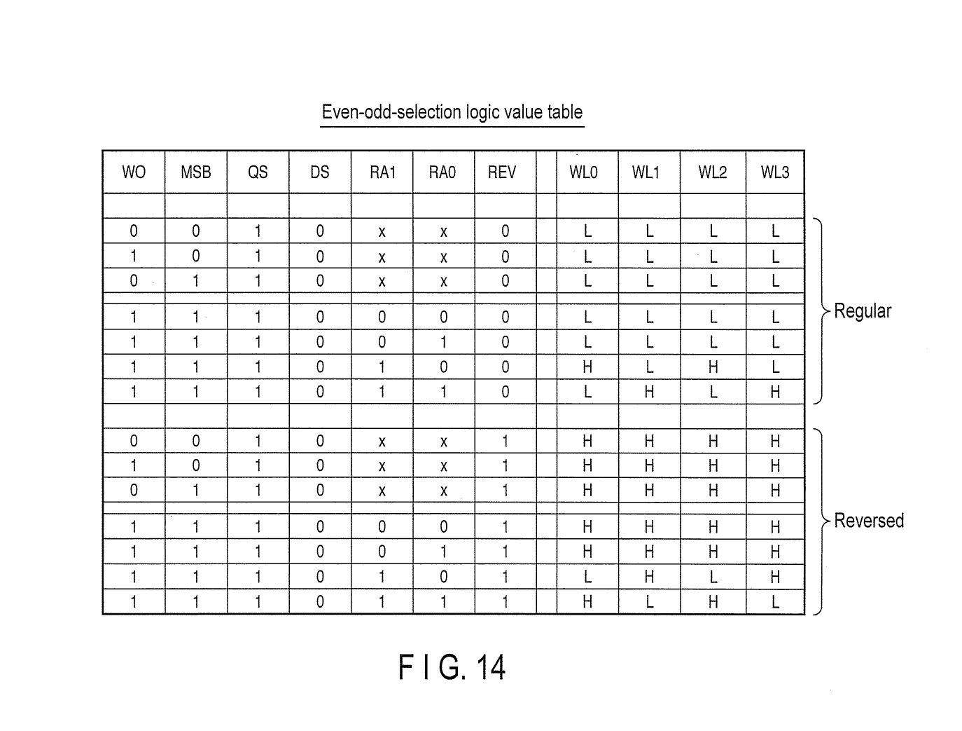

FIG. 14 is an even-odd-selection logic value table that selects odd-numbered or even-numbered word lines simultaneously. The odd-numbered word lines WL1, WL3 or the even-numbered word lines WL0, WL2 can be selected simultaneously by setting the double-selection signal DS to a low level and the quadruple-selection signal QS to a high level. A reversed selection in which the logic of the word lines WL0 to WL3 is reversed can be made by setting the adverse selection signal REV to a high level.

### [5. Effect]

In the present embodiment, as described above, one or two word lines of a plurality of word lines disposed in the selected memory cell block are selected in an erasing operation. Then, data of memory cells connected to the selected word line is erased by applying a negative voltage (−8 V) for erasing to the selected word line only and applying a high-level voltage (3 V) to non-selected word lines.

Therefore, according to the present embodiment, an erasing operation on a memory cell group in units smaller than the memory cell block BLK can be performed. Accordingly, the number of erased memory cells can be reduced so that rewrite processing of a 2Tr flash memory can be reduced. As a result, the life of the 2Tr flash memory can be prolonged.

When the potential of the p-type well region 202 is recovered to 0 V after erasing, the potential of the p-type well region 202 is set to 3 V and subsequently, all word lines, all select gate lines, and the source line are set to 0 V, and then the potential of the p-type well region 202 is set to 0 V. Accordingly, erroneous erasing due to disturbances can be suppressed. As a result, data of memory cells that should not be erased can be held.

A predetermined number of word lines in various combinations of a plurality of word lines disposed in the selected memory cell block can be selected and operated. Accordingly, an erasing operation can be performed efficiently, so that rewrite processing of a 2Tr flash memory can be reduced.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A nonvolatile semiconductor memory device comprising:
semiconductor regions provided on a substrate and electrically separated from each other;
a memory cell block provided in each of the semiconductor regions and comprising nonvolatile memory cells arranged in a matrix form, each of the memory cells comprising a memory transistor and a select transistor connected in series, the memory transistor comprising a charge storage layer and a control gate;
word lines connected to control gates of memory transistors so as to commonly connect memory transistors in a same row;
select gate lines connected to gates of select transistors so as to commonly connect select transistors in a same row; and
a row decoder configured to apply a first negative voltage to a selected word line from which data is erased, and to apply a second positive voltage to a non-selected word lines from which data is not erased while an erasing voltage is applied to the semiconductor region upon erasing operation.

2. The device of claim 1, wherein the second voltage is lower than the erasing voltage.

3. The device of claim 1, wherein
the row decoder selects a predetermined number of selected word lines simultaneously upon the erasing operation, and
the predetermined number is two or more and less than the number of all word lines in the memory cell block.

4. The device of claim 1, wherein the row decoder selects odd-numbered selected word lines simultaneously upon the erasing operation.

5. The device of claim 1, wherein the row decoder selects even-numbered selected word lines simultaneously upon the erasing operation.

6. The device of claim 1, further comprising a voltage switch circuit configured to execute a first stage in which a third voltage between the erasing voltage and a ground voltage is temporarily applied to the semiconductor region after the data of the selected word line is erased.

7. The device of claim 6, wherein
the row decoder executes a second stage in which a ground voltage is applied to all word lines after the first stage, and
the voltage switch circuit executes a third stage in which the ground voltage is applied to the semiconductor region after the second stage.

8. The device of claim 1, further comprising a select decoder configured to set the select gate lines into a floating state upon the erasing operation.

9. The device of claim 1, further comprising a diode having an anode connected to the semiconductor region and a cathode connected to each of the select gate lines.

10. The device of claim 1, further comprising:
a source line commonly connected to sources of the select transistors; and
a driver configured to set the source line into a floating state upon the erasing operation.
